(19) United States
(12) Patent Application Publication
(10) Pub. No.: US 2026/0362926 A1
(43) Pub. Date: Nov. 12, 2026

(54) DISPLAY APPARATUS AND ELECTRONIC APPARATUS INCLUDING THE SAME

(71) Applicant: Samsung Display Co., Ltd., Yongin-si (KR)

(72) Inventors: KANGMOON JO, Yongin-si (KR); DONGHYEON KI, Yongin-si (KR); KYUNGHOON PARK, Yongin-si (KR); SEONGYOUNG LEE, Yongin-si (KR)

(73) Assignee: Samsung Display Co., Ltd., Yongin-si (KR)

(21) Appl. No.: 19/671,848

(22) Filed: May 8, 2026

(30) Foreign Application Priority Data
May 9, 2025 (KR) 10-2025-0060448

(51) Int. Cl. H10K 59/131; H10K 59/12; H10K 59/121

(52) U.S. Cl. CPC H10K 59/1315; H10K 59/1201; H10K 59/1213; H10K 59/1216

(57) ABSTRACT

A display apparatus includes two pixels adjacent to each other in a first direction, wherein the two pixels respectively include a light-emitting device, and a transistor and a capacitor electrically connected to the light-emitting device, the capacitor includes a bottom metal, a gate pattern, and a source/drain pattern stacked in this order, and a signal line extending in a second direction perpendicular to the first direction between the respective bottom metals of the two pixels, and in a same layer as the respective bottom metals.

### CROSS-REFERENCE TO RELATED APPLICATION

This application is based on and claims priority under 35 U.S.C. §119 to Korean Patent Application No. 10-2025-0060448, filed on May 9, 2025, in the Korean Intellectual Property Office, the disclosure of which is incorporated by reference herein in its entirety.

### BACKGROUND

### Field

Embodiments relate to a display apparatus and an electronic apparatus including the same.

### Description of Related Art

Display apparatuses are for displaying images, and recently, light-emitting diode displays have drawn attention as self-luminous display apparatuses.

A light-emitting display apparatus has self-luminous characteristics and, unlike a liquid-crystal display apparatus, does not require a separate light source, allowing it to be thinner and lighter. In addition, a light-emitting display apparatus exhibits high-quality characteristics such as low power consumption, high luminance, and a high response speed.

In general, a light-emitting display apparatus may include a plurality of pixels, and each pixel may include a plurality of transistors, capacitors, and light-emitting devices.

The above-described information is only for enhancement of understanding of the background of the present disclosure, and thus may contain information that does not constitute the related art.

### SUMMARY

Embodiments of the present disclosure may provide a display apparatus having stable operation and improved display quality, and an electronic apparatus including the display apparatus.

However, the objectives of the present disclosure are not limited to the foregoing, and other unmentioned objectives will be clearly understood by those of skill in the art from the following description.

One or more embodiments of the present disclosure may provide a display apparatus including two pixels adjacent to each other in a first direction, wherein the two pixels respectively include a light-emitting device, and a transistor and a capacitor electrically connected to the light-emitting device, wherein the capacitor includes a bottom metal, a gate pattern, and a source/drain pattern sequentially stacked, and a signal line extending in a second direction perpendicular to the first direction between the respective bottom metals of the two pixels, and in a same layer as the respective bottom metals.

In one or more embodiments, with regard to one or both of the two pixels, a shortest distance between the signal line and the bottom metal in the first direction is greater than a shortest distance between the signal line and the source/drain pattern in the first direction.

In one or more embodiments, with regard to one or both of the two pixels, a shortest distance between the signal line and the gate pattern in the first direction is greater than a shortest distance between the signal line and the source/drain pattern in the first direction, and a shortest distance between the signal line and the bottom metal in the first direction.

In one or more embodiments, the signal line may be a driving voltage line.

In one or more embodiments, the display apparatus may further include a sub-voltage line in a same layer as the source/drain pattern, and on the driving voltage line.

In one or more embodiments, the signal line may be a data line.

In one or more embodiments, the data line may include a first data line and a second data line apart from each other in the first direction.

In one or more embodiments, with regard to one or both of the two pixels, in the capacitor, an entirety of the gate pattern is within an area of the source/drain pattern in a third direction perpendicular to the first direction and the second direction.

In one or more embodiments, with regard to one or both of the two pixels, in the capacitor, an entirety of the gate pattern is within an area of the bottom metal in a third direction perpendicular to the first direction and the second direction.

In one or more embodiments, with regard to one or both of the two pixels, in the capacitor, an entirety of the bottom metal is within an area of the source/drain pattern in a third direction perpendicular to the first direction and the second direction.

One or more embodiments of the present disclosure may provide a display apparatus comprising two pixels adjacent to each other in a first direction, each pixel comprising a capacitor comprising a bottom metal, a gate pattern, and a source/drain pattern that are stacked in this order; and a signal line between respective bottom metals of the two pixels, wherein, with regard to one or both of the two pixels, a shortest distance between the signal line and the gate pattern in the first direction is greater than: a shortest distance between the signal line and the source/drain pattern in the first direction, and a shortest distance between the signal line and the bottom metal in the first direction.

One or more embodiments of the present disclosure may provide an electronic apparatus comprising a processor configured to provide image data; and a display apparatus configured to receive the image data and display an image based on the image data, wherein the display apparatus comprises two pixels adjacent to each other in a first direction, each pixel comprising a capacitor comprising a bottom metal, a gate pattern, and a source/drain pattern stacked in this order, a signal line between respective bottom metals of the two pixels, wherein, with regard to one or both of the two pixels, a shortest distance between the signal line and the bottom metal is greater than a shortest distance between the signal line and the source/drain pattern.

In one or more embodiments, with regard to one or both of the two pixels, a shortest distance between the signal line and the gate pattern is greater than the shortest distance between the signal line and the source/drain pattern, and the shortest distance between the signal line and the bottom metal.

In one or more embodiments, the signal line may be a driving voltage line.

In one or more embodiments, the electronic apparatus may further include a sub-voltage line in a same layer as the source/drain pattern, and on the driving voltage line.

In one or more embodiments, the signal line is a data line.

In one or more embodiments, the data line may include a first data line and a second data line apart from each other in the first direction.

In one or more embodiments, with regard to one or both of the two pixels in plan view, in the capacitor, an entirety of the gate pattern is within an area of the source/drain pattern.

In one or more embodiments, with regard to one or both of the two pixels in plan view, in the capacitor, an entirety of the gate pattern is within an area of the bottom metal.

In one or more embodiments, with regard to one or both of the two pixels in plan view, in the capacitor, an entirety of the bottom metal is within an area of the source/drain pattern.

The above-described summary is provided to introduce a selection of the disclosure, in a simplified format, that are further described in the detailed description of the disclosure. This summary is neither intended to identify key or essential aspects of the disclosure, nor is it intended to determine the scope of the disclosure.

### BRIEF DESCRIPTION OF DRAWINGS

The accompanying drawings illustrate preferred embodiments of the present disclosure, and together with the description of the present disclosure to be provided below, serve to provide further understanding of the technical features of the present disclosure, and therefore, the present disclosure should not be interpreted as being limited to the drawings in which:

FIG. 1 is a perspective view schematically illustrating a display apparatus according to an embodiment of the present disclosure;

FIG. 2 is a cross-sectional view schematically illustrating the display apparatus of FIG. 1, taken along line I-I';

FIG. 3 is a plan view schematically illustrating a display panel according to an embodiment of the present disclosure;

FIG. 4 is a circuit diagram of one pixel of a display apparatus according to an embodiment;

FIG. 5 is a plan view illustrating a portion of a display apparatus according to an embodiment;

FIG. 6 is a cross-sectional view schematically illustrating the display apparatus of FIG. 5, taken along line II-II';

FIGS. 7 -10 are plan views sequentially illustrating a display apparatus in a manufacturing sequence thereof, according to an embodiment;

FIG. 11 is a plan view illustrating a portion of a display apparatus according to another embodiment;

FIG. 12 is a cross-sectional view schematically illustrating the display apparatus of FIG. 11, taken along line III-III';

FIG. 13 is a block diagram of an electronic apparatus according to an embodiment of the present disclosure; and

FIG. 14 is a set of schematic diagrams of electronic apparatuses according to various embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

As the present disclosure allows for various changes and numerous embodiments, particular embodiments will be illustrated in the drawings and described in detail. Advantages and features of the present disclosure and a method of achieving the same should become clear with embodiments described below in detail with reference to the drawings. However, the present disclosure is not limited to the embodiments disclosed below, but may be implemented in various forms.

For convenience of description, the magnitude of components in the drawings may be exaggerated or reduced. For example, because the size and/or thickness of each component illustrated in the drawing may be arbitrarily shown for convenience of description, the present disclosure is not necessarily limited to those illustrated in the drawing.

Hereinafter, preferred embodiments will be described below in detail with reference to the accompanying drawings, and in describing the embodiments with reference to the drawings, the same or corresponding components are given the same reference numerals, and redundant descriptions thereof will be omitted.

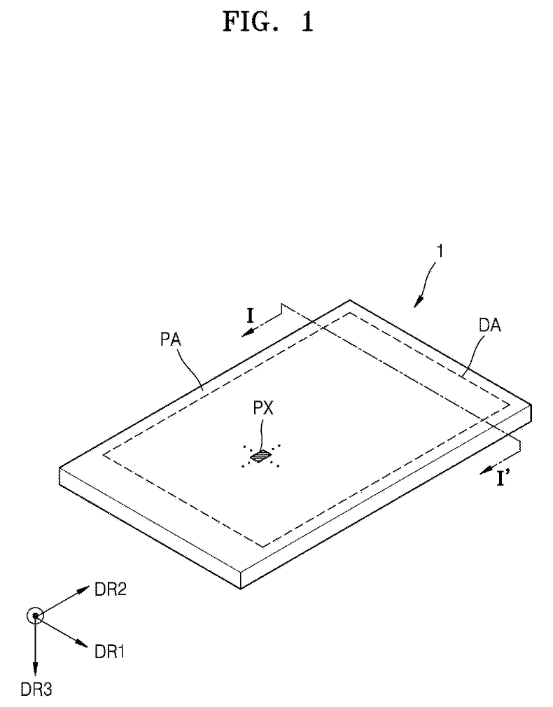

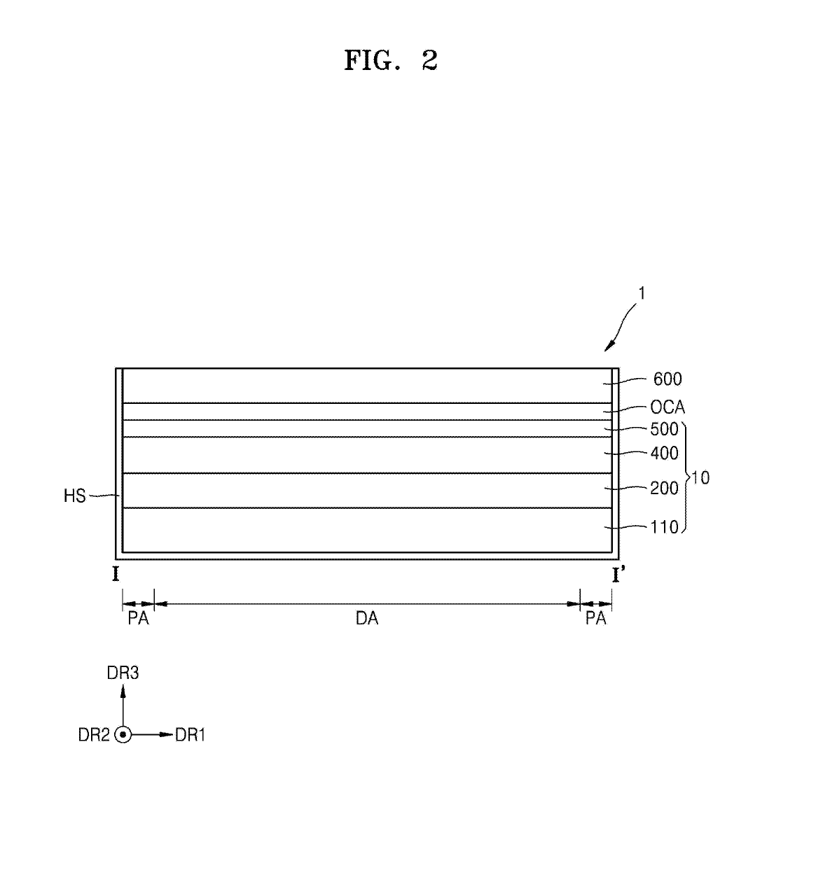

FIG. 1 is a perspective view schematically illustrating a display apparatus according to an embodiment of the present disclosure.

A display apparatus 1 is for displaying a moving image or a still image, and may be used as a display screen for various products, including portable display apparatuses such as a mobile phone, a smart phone, a tablet personal computer, a mobile communication terminal, an electronic organizer, an electronic book, a portable multimedia player (PMP), a navigation device, or an ultra-mobile personal computer (UMPC), as well as a television, a notebook computer, a monitor, a billboard, and an internet-of-things (IoT) device. In some embodiments, the display apparatus 1 according to an embodiment may be used for wearable devices such as a smart watch, a watch phone, a glasses-type display, or a head-mounted display (HMD). In some embodiments, the display apparatus 1 according to an embodiment may be used for a center information display (CID) arranged on an instrument panel, center fascia, or dashboard of a vehicle, a room mirror display used in place of side mirrors of a vehicle, or a display for a rear-seat entertainment system, which is arranged on a rear surface of a front seat. The display apparatus 1 is bendable, foldable, or rollable. For convenience of description, FIG. 1 illustrates that the display apparatus 1 according to an embodiment is used as a smart phone.

The display apparatus 1 may have a rectangular shape in a plan view. For example, as illustrated in FIG. 1, the display apparatus 1 may have a planar rectangular shape with short sides in a first direction DR1 and long sides in a second direction DR2. The corners where the short sides in the first direction DR1 and the long sides in the second direction DR2 meet may be rounded with a predetermined curvature or may be right-angled. The planar shape of the display apparatus 1 is not limited to a rectangle, but may be another polygonal shape, an elliptical shape, or an irregular shape.

The display apparatus 1 may include a display area DA in which an image is displayed, and a peripheral area PA surrounding an outside of the display area DA. The peripheral area PA may be an area in which pixels are not arranged and thus no images are displayed. For example, the peripheral area PA may be a dead space.

The display area DA is a portion for displaying an image, and a plurality of pixels PX may be arranged in the display area DA. Each of the pixels PX may refer to a single sub-pixel, and may include a display apparatus such as a light-emitting device. The display apparatus may be arranged on a substrate 110 in the display area DA. For example, the pixel PX may emit red, green, blue, or white light.

FIG. 2 is a cross-sectional view schematically illustrating the display apparatus of FIG. 1, taken along line I-I'.

Referring to FIG. 2, the display apparatus 1 may include a display panel 10 and a housing HS accommodating the display panel 10.

The display panel 10 may include the substrate 110, a display layer 200, an input sensing layer 400, an optical functional layer 500, and a cover window 600.

The display layer 200 may include display apparatuses (or light-emitting devices) that emit light to display an image, and pixel circuits connected to the respective display apparatuses for applying an electrical signal thereto. The display apparatus may include a light-emitting device, for example, an organic light-emitting device that includes an organic light-emitting layer.

The input sensing layer 400 may obtain coordinate information corresponding to an external input, for example, a touch event. The input sensing layer 400 may include sensing electrodes (or touch electrodes) and trace lines connected to the sensing electrodes. The input sensing layer 400 may be arranged on the display layer 200. The input sensing layer 400 may sense an external input by using a mutual capacitance method and/or a self-capacitance method.

The input sensing layer 400 may be formed directly on the display layer 200, or may be formed separately and then attached to the display layer 200 via an adhesive layer, such as an optically clear adhesive. For example, a process of forming the input sensing layer 400 may be consecutively performed after a process of forming the display layer 200, and in this case, an adhesive layer may not be arranged between the input sensing layer 400 and the display layer 200. Although FIG. 2 illustrates that the input sensing layer 400 is arranged between the display layer 200 and the optical functional layer 500, in another embodiment, the input sensing layer 400 may be arranged on the optical functional layer 500.

The optical functional layer 500 may include an anti-reflection layer. The anti-reflection layer may reduce the reflectance of external light incident on the display panel 10 through the cover window 600. The anti-reflection layer may include a retarder and a polarizer. The retarder may be a film-type or a liquid-crystal-coating-type. Likewise, the polarizer may be a film-type or a liquid-crystal-coating-type. A film-type polarizer may include a stretched synthetic resin film, and a liquid-crystal-coating-type polarizer may include liquid crystals in a certain arrangement.

In one or more embodiments, the anti-reflection layer may include a black matrix and color filters. The color filters may be arranged based on the color of light emitted from each of the light-emitting devices in the display layer 200. In one or more embodiments, the anti-reflection layer may include a destructive interference structure. The destructive interference structure may include a first reflective layer and a second reflective layer that are arranged on different layers. First reflected light that is reflected from the first reflective layer, and second reflected light that is reflected from the second reflective layer may destructively interfere with each other, thereby reducing the reflectance of external light.

The optical functional layer 500 may include a lens layer. The lens layer may improve the emission efficiency of light emitted from the display layer 200 or reduce chromatic aberration. The lens layer may include a layer having a concave or convex lens shape, and/or a plurality of layers having different refractive indices. The optical functional layer 500 may include both the anti-reflection layer and the lens layer, or may include any one of them.

The cover window 600 may be arranged above the optical functional layer 500. The cover window 600 may be coupled via an adhesive layer, such as an optically clear adhesive (OCA), that is arranged between the cover window 600 and the optical functional layer 500. The cover window 600 may include a glass material or a plastic material. For example, the cover window 600 may include an ultra-thin glass window. For example, the cover window 600 may include polyethersulfone, polyacrylate, polyetherimide, polyethylene naphthalate, polyethylene terephthalate, polyphenylene sulfide, polyarylate, polyimide, polycarbonate, cellulose acetate propionate, or the like.

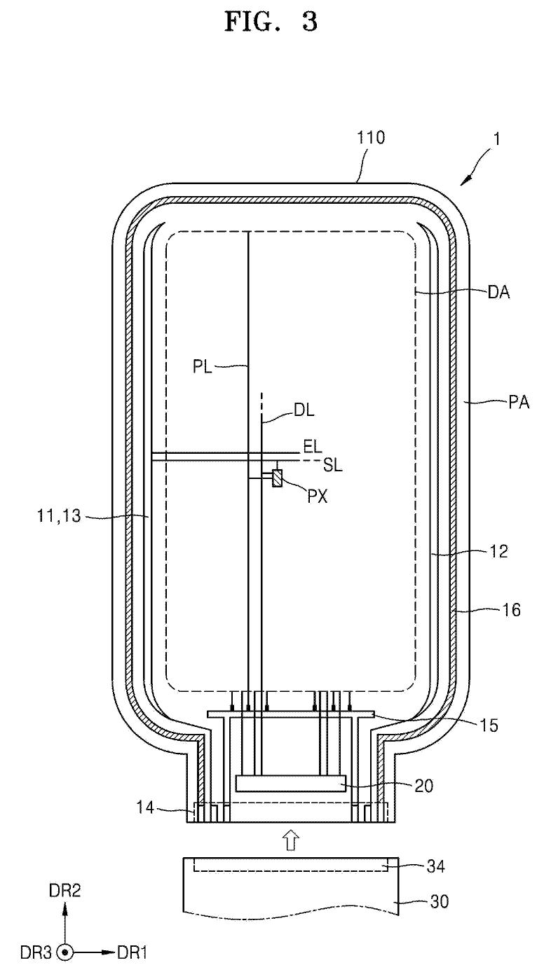

FIG. 3 is a plan view schematically illustrating a display panel according to an embodiment of the present disclosure.

Referring to FIG. 3, the display panel 10 includes the display area DA and the peripheral area PA outside the display area DA.

The display panel 10 includes the substrate 110. In the present specification, because the display panel 10 may include the display area DA and the peripheral area PA, the substrate 110 may also be interpreted as including the display area DA and the peripheral area PA. The substrate 110 may include the display area DA and the peripheral area PA surrounding the display area DA.

The display area DA is a portion for displaying an image, and a plurality of pixels PX may be arranged in the display area DA. Although FIG. 3 illustrates that the display area DA has the shape of a rectangle with rounded corners, the present disclosure is not limited thereto. As described above, the display area DA may have various shapes, for example, a polygon with N sides (where N is a natural number of 3 or greater), a circle, or an ellipse, but is not particularly limited thereto, and the display area DA may have various other shapes as well.

The peripheral area PA may be arranged outside the display area DA. Peripheral circuits for driving the pixels PX may be arranged in the peripheral area PA. For example, a first scan driving circuit 11, a second scan driving circuit 12, a light-emission control driving circuit 13, a terminal 14, a driving power supply line 15, and a common power supply line 16 may be arranged in the peripheral area PA.

The first scan driving circuit 11 may provide a scan signal to the pixel PX via a scan line SCL. The second scan driving circuit 12 may be arranged parallel to the first scan driving circuit 11, with the display area DA therebetween. Some of the pixels PX arranged in the display area DA may be electrically connected to the first scan driving circuit 11, and the other pixels PX may be connected to the second scan driving circuit 12. The second scan driving circuit 12 may be omitted, and all the pixels PX arranged in the display area DA may be electrically connected to the first scan driving circuit 11.

The light-emission control driving circuit 13 may be arranged on the same side as the first scan driving circuit 11, and may provide a light-emission control signal to the pixels PX via a light-emission control line EL. Although FIG. 3 illustrates that the light-emission control driving circuit 13 may be arranged on only one side of the display area DA, the light-emission control driving circuit 13 may also be arranged on opposite sides of the display area DA, similar to the first scan driving circuit 11 and the second scan driving circuit 12.

A driving chip 20 may be arranged in the peripheral area PA. The driving chip 20 may include an integrated circuit for driving the display panel 10. This integrated circuit may be a data driving integrated circuit for generating a data signal, but the present disclosure is not limited thereto.

The terminal 14 may be arranged in the peripheral area PA. The terminal 14 may be exposed without being covered by an insulating layer, to be electrically connected to a printed circuit board 30. A terminal 34 of the printed circuit board 30 may be electrically connected to the terminal 14 of the display panel 10.

The printed circuit board 30 transmits, to the display panel 10, signals or power from a controller. Control signals generated from the controller may be transmitted to the respective driving circuits via the printed circuit board 30. In one or more embodiments, the controller may supply a driving voltage ELVDD to the driving power supply line 15 and provide a common voltage ELVSS to the common power supply line 16. The driving voltage ELVDD may be supplied to each pixel PX via a driving voltage line PL connected to the driving power supply line 15. The driving power supply line 15 may have a shape that extends in one direction (e.g., the first direction DR1) below the display area DA. The common power supply line 16 may have a loop shape that is open on one side, to partially surround the display area DA.

The controller may generate a data signal, and the generated data signal may be transmitted to an input line via the driving chip 20 and then transmitted to the pixel PX via a data line DL connected to the input line. For reference, the term “line” may mean “wiring”, “trace”, “conductor”, and/or “interconnection”, etc. This also applies to embodiments to be described below and modifications thereof.

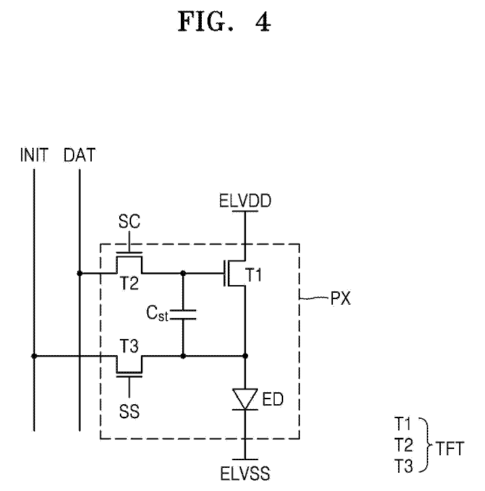

FIG. 4 is a circuit diagram of one pixel of a display apparatus according to an embodiment.

The display apparatus 1 according to an embodiment includes a plurality of pixels PX. As illustrated in FIG. 4, each of the plurality of pixels PX may include a plurality of thin-film transistors TFT, a capacitor Cst, and at least one light-emitting device (e.g., light-emitting diode, or LED) ED. The present embodiment will be described mainly with reference to an example in which one pixel PX includes one light-emitting device ED.

The plurality of transistors TFT include a driving transistor T1, a switching transistor T2, and an initialization transistor T3. The terms “first electrode” and “second electrode” to be described below are used to distinguish between two electrodes located on opposite sides of a channel of each transistor TFT, and may refer to a source electrode or a drain electrode, respectively.

A gate electrode of the driving transistor T1 is connected to one end of the capacitor Cst, a first electrode of the driving transistor T1 is connected to a driving voltage line that transmits the driving voltage ELVDD, and a second electrode of the driving transistor T1 is connected to an anode of the light-emitting device ED and another end of the capacitor Cst. The driving transistor T1 may receive a data voltage DAT according to a switching operation of the switching transistor T2, and supply a driving current to the light-emitting device ED according to a voltage stored in the capacitor Cst.

A gate electrode of the switching transistor T2 is connected to a first scan line that transmits a first scan signal SC, a first electrode of the switching transistor T2 is connected to a data line that may transmit the data voltage DAT or a reference voltage, and a second electrode of the switching transistor T2 is connected to one end of the capacitor Cst and the gate electrode of the driving transistor T1. The switching transistor T2 is turned on according to the first scan signal SC to transmit the reference voltage or the data voltage DAT to the gate electrode of the driving transistor T1 and one end of the capacitor Cst.

A gate electrode of the initialization transistor T3 may be connected to a second scan line that transmits a second scan signal SS, a first electrode of the initialization transistor T3 may be connected to another end of the capacitor Cst, the second electrode of the driving transistor T1, and the anode of the light-emitting device ED, and a second electrode of the initialization transistor T3 may be connected to an initialization voltage line that transmits an initialization voltage INIT. The initialization transistor T3 may be turned on according to the second scan signal SS to transmit the initialization voltage INIT to the anode of the light-emitting device ED and the other end of the capacitor Cst, thereby initializing the voltage of the anode of the light-emitting device ED.

One end of the capacitor Cst may be connected to the gate electrode of the driving transistor T1, and another end of the capacitor Cst may be connected to the first electrode of the initialization transistor T3 and the anode of the light-emitting device ED. A cathode of the light-emitting device ED may be connected to a common voltage line that transmits the common voltage ELVSS.

The light-emitting device ED may emit light with a luminance corresponding to the driving current generated by the driving transistor T1.

An example of an operation of the circuit illustrated in FIG. 4 will be described, specifically, an example of the operation during one frame. Hereinafter, a case in which the transistors TFT are N-type channel transistors will be described as an example, but the present disclosure is not limited thereto.

When one frame begins, during an initialization period, a high-level first scan signal SC and a high-level second scan signal SS may be supplied, such that the switching transistor T2 and the initialization transistor T3 are turned on. Via the turned-on switching transistor T2, a reference voltage from the data line may be supplied to the gate electrode of the driving transistor T1 and one end of the capacitor Cst, and via the turned-on initialization transistor T3, the initialization voltage INIT may be supplied to the second electrode of the driving transistor T1 and the anode of the light-emitting device ED. Accordingly, during the initialization period, the second electrode of the driving transistor T1 and the anode of the light-emitting device ED may be initialized to the initialization voltage INIT. At this time, a difference voltage between the reference voltage and the initialization voltage INIT may be stored in the capacitor Cst.

Next, during a sensing period, when the second scan signal SS becomes a low level while the high-level first scan signal SC may be maintained, the switching transistor T2 remains turned on, and the initialization transistor T3 may be turned off. Via the turned-on switching transistor T2, the gate electrode of the driving transistor T1 and one end of the capacitor Cst maintain the reference voltage, and via the turned-off initialization transistor T3, the second electrode of the driving transistor T1 and the anode of the light-emitting device ED may be disconnected from the initialization voltage INIT. Accordingly, a current flows from the first electrode to the second electrode of the driving transistor T1, and when the voltage of the second electrode becomes “reference voltage - Vth”, the driving transistor T1 may be turned off. Vth denotes the threshold voltage of the driving transistor T1. At this time, a voltage difference between the gate electrode and the second electrode of the driving transistor T1 is stored in the capacitor Cst, and the sensing of the threshold voltage Vth of the driving transistor T1 may be completed. The deviation in characteristics of the driving transistor T1, which may differ from pixel to pixel, may be externally compensated for by generating a compensated data signal that reflects characteristic information sensed during the sensing period.

Next, during a data input period, when a high-level first scan signal SC and a low-level second scan signal SS are supplied, the switching transistor T2 is turned on and the initialization transistor T3 is turned off. Via the turned-on switching transistor T2, the data voltage DAT from the data line is supplied to the gate electrode of the driving transistor T1 and one end of the capacitor Cst. At this time, the second electrode of the driving transistor T1 and the anode of the light-emitting device ED may maintain substantially the same potential as in the sensing period, due to the turned off driving transistor T1.

Next, during a light-emission period, the driving transistor T1, which has been turned on by the data voltage DAT transmitted to its gate electrode, may generate a driving current corresponding to the data voltage DAT, and the light-emitting device ED may emit light based on the driving current.

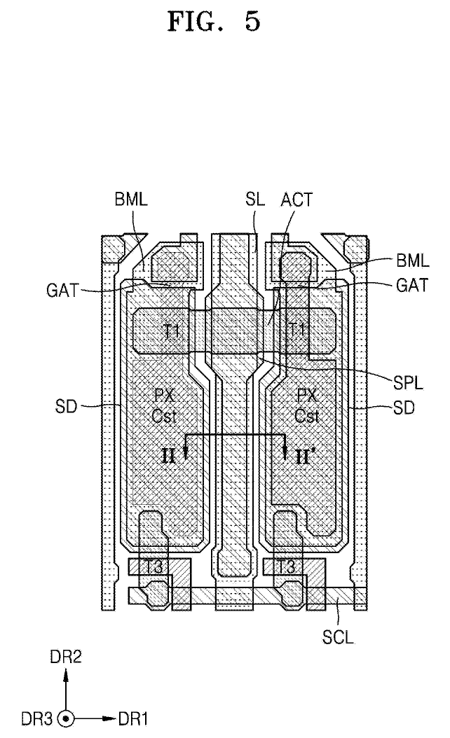

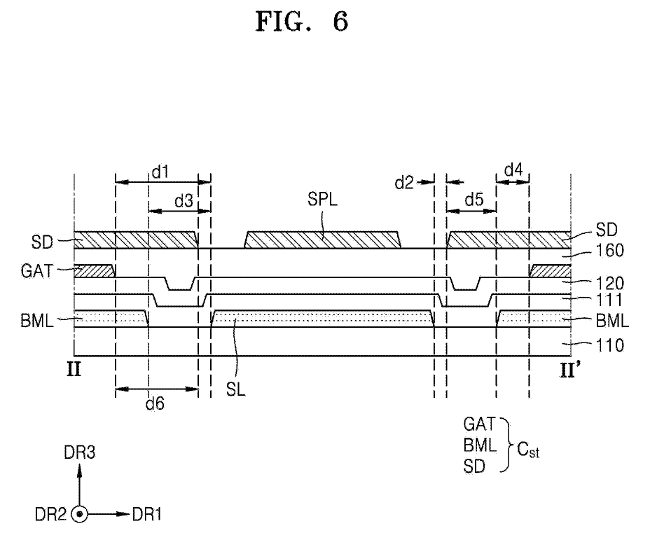

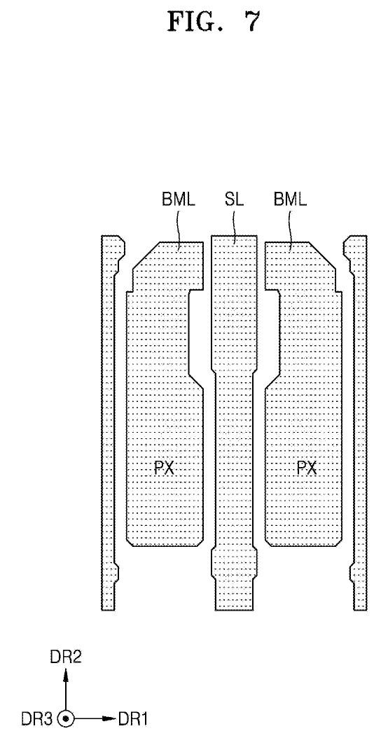

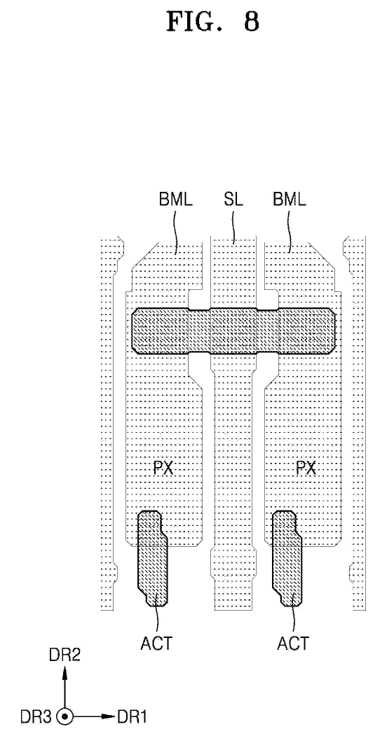

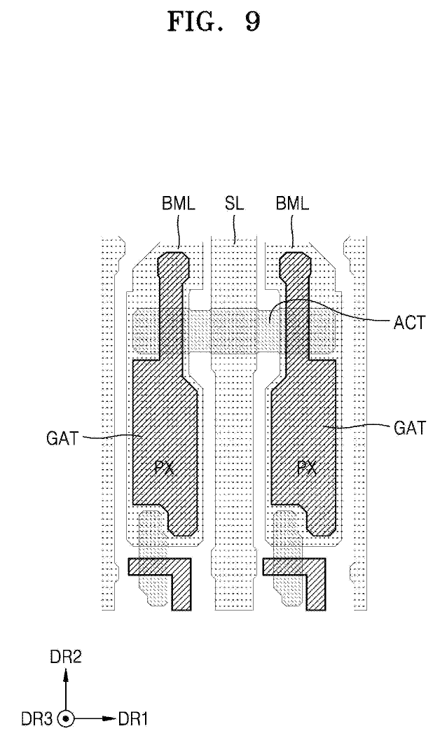

FIG. 5 is a plan view illustrating a portion of a display apparatus according to an embodiment, FIG. 6 is a cross-sectional view schematically illustrating the display apparatus of FIG. 5, taken along line II-II', and FIGS. 7-10 are plan views sequentially illustrating a display apparatus in a manufacturing sequence thereof, according to an embodiment. FIGS. 5-10 illustrate portions of two adjacent pixels of a display apparatus according to an embodiment, and such pixels may be repeatedly arranged. FIGS. 2-10 illustrate two adjacent pixels of a display apparatus according to one or more embodiments, and such pixels may be repeatedly arranged. Unless otherwise indicated, as used herein with regard to any of the respective pixels, any two pixels are considered “adjacent” or “adjacent to” one another so long as no other pixel occupies a space between the two pixels. That is, two pixels are considered adjacent each other if the two pixels are not separated from each other by an intervening pixels.

Referring to FIGS. 5 - 10, the display apparatus 1 may include two pixels PX adjacent to each other in the first direction DR1. Each pixel PX may include a light-emitting device ED, and transistors TFT and a capacitor Cst that are electrically connected to the light-emitting device ED.

The capacitor Cst may include a bottom metal BML, a gate pattern GAT, and a source/drain pattern SD that are sequentially stacked in a third direction DR3.

Here, each of a plurality of pixels PX may refer to a portion or an area in which the components included in one above-described pixel PX, that is, the plurality of transistors TFT, the capacitor Cst, and the light-emitting device ED, are formed.

The display apparatus according to an embodiment may include a substrate 110. The substrate 110 may include an insulating material, such as glass or plastic, and may have flexibility.

The substrate 110 may include a first base layer, a first barrier layer, a second base layer, and a second barrier layer. In an embodiment, the first base layer, the first barrier layer, the second base layer, and the second barrier layer may be sequentially stacked in a thickness direction (i.e., in the third direction DR3) of the substrate 110.

At least one of the first base layer and the second base layer may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer and the second barrier layer are barrier layers configured to prevent contamination due to the penetration of external foreign substances, and may each include a single layer or multiple layers including an inorganic material such as silicon nitride (SiNₓ), silicon oxide (SiO₂), and/or silicon oxynitride (SiON).

The bottom metal BML may be formed on the substrate 110, and a buffer layer 111 may be formed on the bottom metal BML.

The bottom metal BML may be arranged on the substrate 110. The bottom metal BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). The bottom metal BML may include a single layer or multiple layers formed of the above materials.

The bottom metal BML may block light incident from below the display apparatus 1, thereby preventing the light from being provided to an active pattern ACT of the transistor TFT. The bottom metal BML may be a first conductive layer arranged between the substrate 110 and the buffer layer 111.

The bottom metal BML may be arranged to overlap with the active pattern ACT in plan view, so as to act as a protective layer that prevents degradation of the electrical characteristics of the active pattern ACT constituting the transistor TFT. For example, the bottom metal BML may be configured to protect the transistors TFT from a laser or moisture penetrating from below the substrate 110, which is a flexible substrate, during a process of manufacturing the display apparatus 1.

The buffer layer 111 may be arranged over the entirety of the substrate 110 on which the bottom metal BML is arranged.

The buffer layer 111 may prevent the diffusion of impurities into the transistors TFT. The buffer layer 111 may include an inorganic insulating film including an inorganic material. The buffer layer 111 may include at least one of silicon nitride (SiNₓ), silicon oxide (SiOₓ), silicon oxynitride (SiOₓN_{y}), and aluminum oxide (AlOₓ). The buffer layer 111 may be provided as a single layer, but may also be provided as at least two layers. In a case in which the buffer layer 111 is provided as multiple layers, the layers may be formed of the same material or different materials. The buffer layer 111 may be omitted depending on the material of the substrate 110, process conditions, or the like.

The active pattern ACT may be arranged on the buffer layer 111. The active pattern ACT may include amorphous silicon or polycrystalline silicon. In one or more embodiments, the active pattern ACT may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn).

The active pattern ACT may include, for each transistor TFT, a source region and a drain region doped with impurities, and a channel region between the source region and the drain region.

A first gate insulating layer 120 may be arranged over the entirety of the buffer layer 111 on which the active pattern ACT is arranged. The first gate insulating layer 120 may cover the active pattern ACT on the buffer layer 111, and may be arranged with a substantially uniform thickness along the profile of the active pattern ACT. The first gate insulating layer 120 may include a silicon compound, a metal oxide, or the like. The first gate insulating layer 120 may include a plurality of layers.

The gate pattern GAT may be arranged on the first gate insulating layer 120. A region of the gate pattern GAT may overlap with the active pattern ACT in the third direction DR3. The gate pattern GAT may be formed to include one or more of a metal, an alloy, a metal nitride, a conductive metal oxide, a transparent conductive material, or the like. The gate pattern GAT may be the gate electrode of the transistor TFT described above.

The active pattern ACT and the gate pattern GAT may form the transistor TFT. For example, the transistor TFT may be any one of the transistors described above with reference to FIG. 4.

A second gate insulating layer 160 may be arranged over the entirety of the first gate insulating layer 120 on which the gate pattern GAT is arranged.

The second gate insulating layer 160 may sufficiently cover the gate pattern GAT on the first gate insulating layer 120, and may also have a substantially flat top surface that does not exhibit a step-height difference over the gate pattern GAT. As another example, the second gate insulating layer 160 may cover the gate pattern GAT on the first gate insulating layer 120, and may be arranged with a substantially uniform thickness along the profile of the gate pattern GAT.

In one or more embodiments, a horizontal distance d1 between an end of the gate pattern GAT and an adjacent end of the signal line SL may be equal to the sum of a horizontal distance d2 between an end of the signal line SL and an adjacent end of the source/drain pattern SD, a horizontal distance d5 between an end of the source/drain pattern SD and an adjacent end of the bottom metal BML, and a horizontal distance d4 between an end of the bottom metal BML and an adjacent end of the gate pattern GAT(referring to FIG. 6).

Under such a configuration, the horizontal distance d1 between the end of the gate pattern GAT and the adjacent end of the signal line SL may be greater than a horizontal distance d3 between the end of the bottom metal BML and the adjacent end of the signal line SL, and a horizontal distance d6 between the end of the gate pattern GAT and the adjacent end of the source/drain pattern SD may be greater. In these embodiments, the horizontal distances d1 to d6 may correspond to distances in the first direction DR1.

The second gate insulating layer 160 may include an inorganic insulating material, such as a silicon compound or a metal oxide, or an organic insulating material. The second gate insulating layer 160 may include a plurality of layers.

The source/drain pattern SD may be arranged on the second gate insulating layer 160. The source/drain pattern SD may include signal lines arranged in the display area DA, such as a source electrode and a drain electrode. In one or more embodiments, the source/drain pattern SD may include a connection electrode arranged in a pad portion of the peripheral area PA.

The source/drain pattern SD may be formed to include one or more of a metal, an alloy, a metal nitride, a conductive metal oxide, a transparent conductive material, or the like. The source/drain pattern SD may include a highly conductive metal such as copper or aluminum. In one or more embodiments, the source/drain pattern SD may have a layered structure including a plurality of layers. For example, the source/drain pattern SD may be a stacked structure (e.g., stacked in the third direction DR3) including a first layer including titanium (Ti), a second layer including aluminum (Al), and a third layer including titanium (Ti).

The source/drain pattern SD may include a source electrode, a drain electrode, and other signal lines.

The source electrode and the drain electrode may be respectively electrically connected to the source region and the drain region of the active pattern ACT through contact holes formed through the first gate insulating layer 120 and the second gate insulating layer 160.

A larger area for the capacitor Cst may enable more stable driving of the display apparatus 1, and may reduce the visibility of screen stains. The display apparatus 1 of the present disclosure includes two adjacent pixels PX, each including the capacitor Cst in which the bottom metal BML, the gate pattern GAT, and the source/drain pattern SD are sequentially stacked in the third direction DR3, however, when the bottom metals BML of the two adjacent pixels PX face each other, it may not be possible to expand the area of the capacitor Cst without increasing the occurrence and/or degree of a parasitic capacitance.

In one or more embodiments, it may be necessary to avoid exposure of the gate pattern GAT in order to prevent and reduce the appearance of stains on the screen of the display apparatus 1, as this may affect other components such as an anode electrode. To this end, the source/drain pattern SD on the gate pattern GAT may be formed to cover the gate pattern GAT. That is, in the capacitor Cst, the entire gate pattern GAT may be located within the area of the source/drain pattern SD in the third direction DR3, which is perpendicular to the first direction DR1 and the second direction DR2. That is, an orthogonal projection of the gate pattern GAT on the substrate 110 may be located entirely within an orthogonal projection of the source/drain pattern SD on the substrate 110.

Furthermore, when the widths increase in the order of the gate pattern GAT, the source/drain pattern SD, and the bottom metal BML, the area of the capacitor Cst corresponds to the area of the gate pattern GAT, and a design for the gate pattern GAT, the source/drain pattern SD, and the bottom metal BML is required that may expand the area of the gate pattern GAT, i.e., the area of the capacitor Cst, while reducing parasitic capacitance within the limited area of the display apparatus 1.

To overcome the limitations on improving the reliability and display quality of the display apparatus 1, which are imposed by the area of the capacitor Cst, a design will be described in detail, including a signal line SL located in the same layer as the bottom metal BML and extending in the second direction DR2 perpendicular to the first direction DR1, between the bottom metals BML respectively included in two pixels PX that are adjacent to each other in the first direction DR1.

The signal line SL, which is located in the same layer as the bottom metal BML and extends in the second direction DR2 perpendicular to the first direction DR1, may be arranged between the bottom metals BML respectively included in two pixels PX that are adjacent to each other in the first direction DR1. The signal line SL may be arranged between the substrate 110 and the buffer layer 111.

The signal line SL is arranged between the bottom metals BML of two respective adjacent pixels PX, and does not form the capacitor Cst, and thus, the source/drain patterns SD on opposite sides of the signal line SL may extend toward the signal line SL.

As the source/drain pattern SD may be expanded in the first direction DR1, the gate pattern GAT may also be expanded in the first direction DR1. As a result, the area of the gate pattern GAT, which is the area of the capacitor Cst, may be increased. That is, the reliability and display quality of the display apparatus 1 may be improved.

It is necessary to secure a gap in the first direction DR1 between the bottom metal BML and the signal line SL to prevent parasitic capacitance, and the width of the bottom metal BML may be reduced because the signal line SL is arranged between the bottom metals BML of two pixels PX adjacent to each other in the first direction DR1. The width of the gate pattern GAT may be expanded by an amount corresponding to the increase in the width of the source/drain pattern SD, but may be less than the width of the bottom metal BML. That is, in the capacitor Cst, the entire gate pattern GAT may be located within the area of the bottom metal BML in the third direction DR3, which is perpendicular to the first direction DR1 and the second direction DR2.

The width of the source/drain pattern SD arranged on the gate pattern GAT may be greater than the width of the bottom metal BML, which may further mitigate and prevent a seam phenomenon on the gate pattern GAT. That is, in the capacitor Cst, the entire bottom metal BML may be located within the area of the source/drain pattern SD in the third direction DR3, which is perpendicular to the first direction DR1 and the second direction DR2. The distances in the first direction DR1 from an end of the signal line SL to the source/drain pattern SD, the bottom metal BML, and the gate pattern GAT may progressively increase.

The shortest distance between the signal line SL and the bottom metal BML in the first direction DR1 may be greater than the shortest distance between the signal line SL and the source/drain pattern SD in the first direction DR1. The shortest distance between the signal line SL and the gate pattern GAT in the first direction DR1 may be greater than both the shortest distance between the signal line SL and the source/drain pattern SD in the first direction DR1, and the shortest distance between the signal line SL and the bottom metal BML in the first direction DR1.

The signal line SL may be formed on the substrate 110 simultaneously with the bottom metal BML. The signal line SL may include the same material as the bottom metal BML.

For example, the signal line SL may be the driving voltage line PL to which the driving voltage ELVDD is applied. However, the present disclosure is not limited thereto, and the signal line SL may be another type of wiring, such as a data line capable of transmitting a reference voltage, a scan line, a common voltage line to which the common voltage ELVSS is applied, or an initialization line to which the initialization voltage INIT is applied.

For example, a sub-voltage line SPL may be further arranged in the same layer as the source/drain pattern SD, on the driving voltage line PL. The sub-voltage line SPL may be connected to the driving voltage line PL through a via hole formed in the first gate insulating layer 120 and the second gate insulating layer 160.

The sub-voltage line SPL may be formed on the second gate insulating layer 160 simultaneously with the source/drain pattern SD. The sub-voltage line SPL may include the same material as the source/drain pattern SD.

In a case in which the signal line SL corresponds to a wiring other than the driving voltage line PL, such as a data line, a scan line, or a common voltage line, an auxiliary line other than the sub-voltage line SPL may be further arranged in the same layer as the source/drain pattern SD, on the signal line SL. That is, the auxiliary line may serve to assist the signal line SL, for example, by lowering the resistance of the signal line SL, depending on the type of the signal line SL.

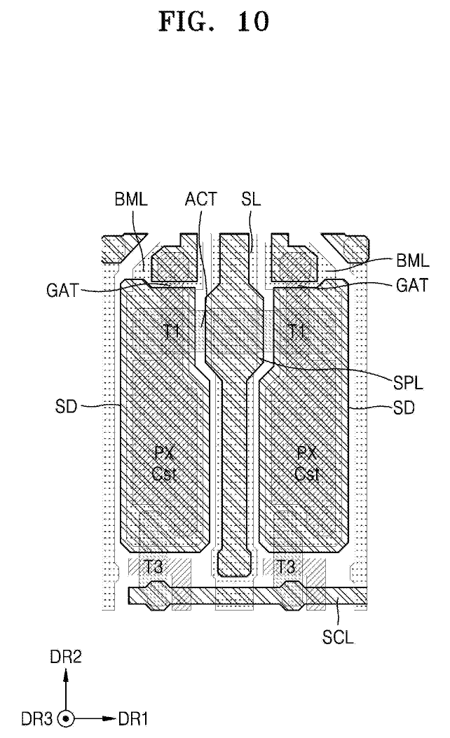

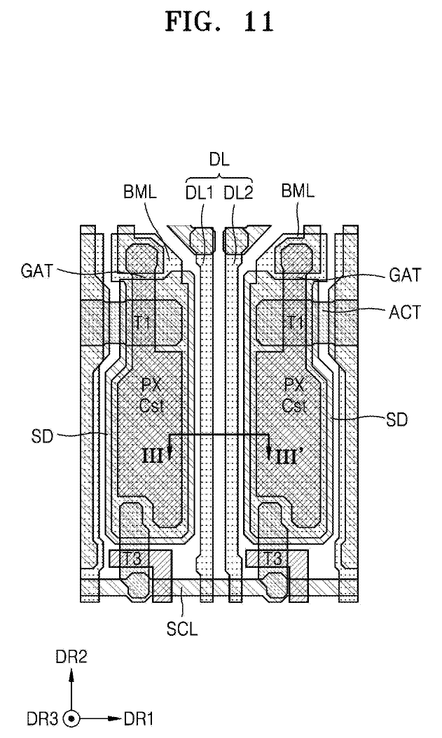

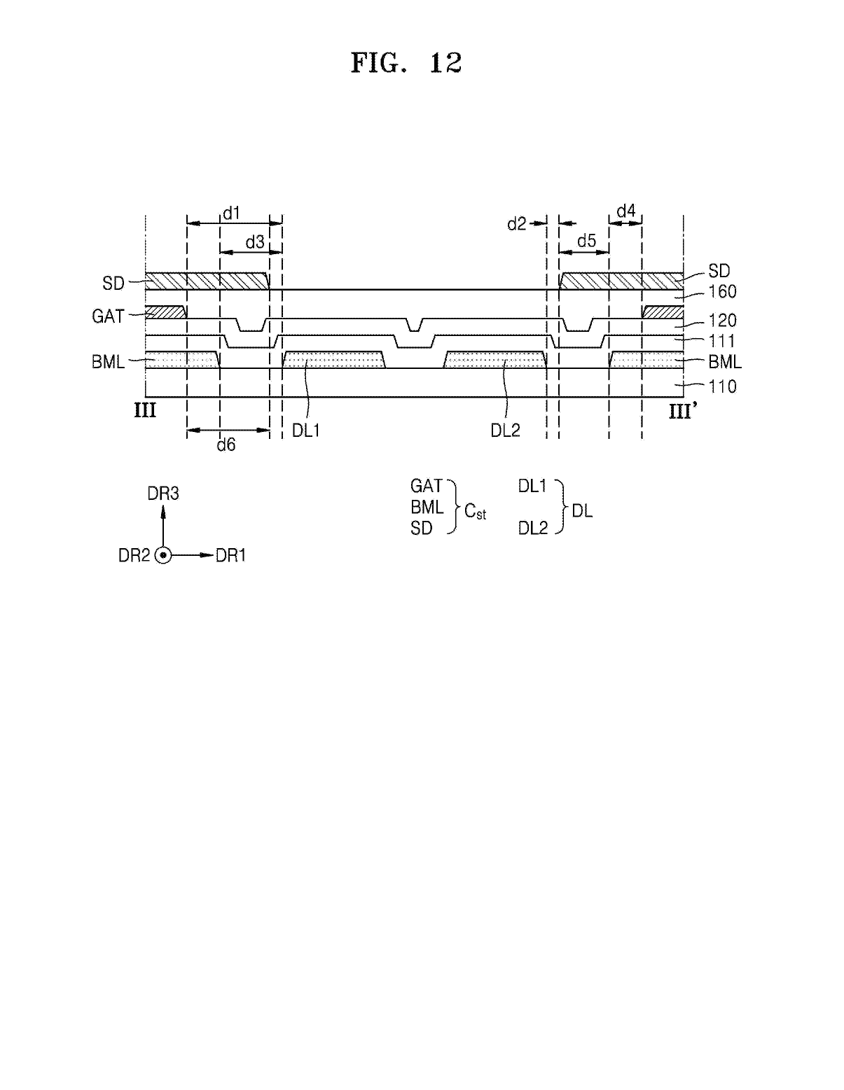

FIG. 11 is a plan view illustrating a portion of a display apparatus according to one or more embodiments, and FIG. 12 is a cross-sectional view schematically illustrating the display apparatus of FIG. 11, taken along line III-III'.

Referring to FIGS. 11 and 12, the display apparatus 1 may include two pixels PX adjacent to each other in the first direction DR1. Each pixel PX may include a light-emitting device ED, and transistors TFT and a capacitor Cst that are electrically connected to the light-emitting device ED.

The capacitor Cst may include a bottom metal BML, a gate pattern GAT, and a source/drain pattern SD that are sequentially stacked in the third direction DR3.

Here, each of a plurality of pixels PX may refer to a portion or an area in which the components included in one above-described pixel PX, that is, the plurality of transistors TFT, the capacitor Cst, and the light-emitting device ED, are formed.

The display apparatus 1 may include a substrate 110, a bottom metal BML on the substrate 110, a buffer layer 111 covering the bottom metal BML, an active pattern ACT on the buffer layer 111, a first gate insulating layer 120 covering the active pattern ACT, a gate pattern GAT on the first gate insulating layer 120, a second gate insulating layer 160 covering the gate pattern GAT, and a source/drain pattern SD on the second gate insulating layer 160. For these components, unless stated otherwise in the following description, the descriptions provided above with reference to FIGS. 1- 10 may be applied.

To overcome the limitations on improving the reliability and display quality of the display apparatus 1, which are imposed by the area of the capacitor Cst, another embodiment design will be described in detail, including a signal line SL located in the same layer as the bottom metal BML and extending in the second direction DR2 perpendicular to the first direction DR1, between the bottom metals BML respectively included in two pixels PX that are adjacent to each other in the first direction DR1.

The signal line SL, which may be located in the same layer as the bottom metal BML and may extend in the second direction DR2 perpendicular to the first direction DR1, may be arranged between the bottom metals BML respectively included in two pixels PX that are adjacent to each other in the first direction DR1. The signal line SL may be arranged between the substrate 110 and the buffer layer 111.

The signal line SL may be arranged between the bottom metals BML of two respective adjacent pixels PX, and does not form the capacitor Cst, and thus, the source/drain patterns SD on opposite sides of the signal line SL may extend toward the signal line SL. The signal line SL may include a plurality of lines.

As the source/drain pattern SD may be expanded in the first direction DR1, the gate pattern GAT may also be expanded in the first direction DR1. As a result, the area of the gate pattern GAT, which is the area of the capacitor Cst, may be increased. That is, the reliability and display quality of the display apparatus 1 may be improved.

It is necessary to secure a gap in the first direction DR1 between the bottom metal BML and the signal line SL to prevent parasitic capacitance, and the width of the bottom metal BML may be reduced because the signal line SL is arranged between the bottom metals BML of two pixels PX adjacent to each other in the first direction DR1. The width of the gate pattern GAT may be expanded by an amount corresponding to the increase in the width of the source/drain pattern SD, but may be less than the width of the bottom metal BML.

The width of the source/drain pattern SD arranged on the gate pattern GAT may be greater than the width of the bottom metal BML, which may further mitigate and prevent a seam phenomenon on the gate pattern GAT. The distances in the first direction DR1 from an end of the signal line SL to the source/drain pattern SD, the bottom metal BML, and the gate pattern GAT may progressively increase.

The shortest distance between the signal line SL and the bottom metal BML in the first direction DR1 may be greater than the shortest distance between the signal line SL and the source/drain pattern SD in the first direction DR1. The shortest distance between the signal line SL and the gate pattern GAT in the first direction DR1 may be greater than both the shortest distance between the signal line SL and the source/drain pattern SD in the first direction DR1, and the shortest distance between the signal line SL and the bottom metal BML in the first direction DR1.

The signal line SL may be formed on the substrate 110 simultaneously with the bottom metal BML. The signal line SL may include the same material as the bottom metal BML.

For example, the signal line SL may be a data line DL capable of transmitting a reference voltage. However, the present disclosure is not limited thereto, and the signal line SL may be another type of wiring, such as a driving voltage line to which the driving voltage ELVDD is applied, a scan line, a common voltage line to which the common voltage ELVSS is applied, or an initialization line to which the initialization voltage INIT is applied.

For example, the data line DL may include a first data line DL1 and a second data line DL2, which are spaced apart from each other in the first direction DR1 and extend in the second direction DR2. However, the present disclosure is not limited thereto, and the data line DL may further include a third data line.

Unlike in the display apparatus 1 of FIGS. 5 -10, an auxiliary line, such as the sub-voltage line SPL of FIG. 6, may not be arranged on the signal line SL.

The display apparatus 1 according to one or more embodiments may be applied to various electronic apparatuses 1000. The electronic apparatus 1000 according to one or more embodiments may include the above-described display apparatus 1, and may further include a module or apparatus having other additional functions in addition to the display apparatus 1.

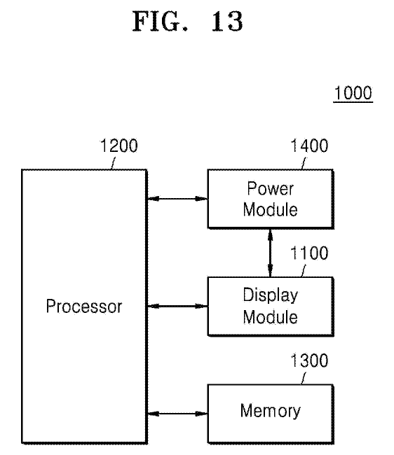

FIG. 13 is a block diagram of an electronic apparatus according to an embodiment of the present disclosure.

Referring to FIG. 13, the electronic apparatus 1000 according to one or more embodiments may include a display module 1100, a processor 1200, a memory 1300, and a power module 1400.

The processor 1200 may include one or more processors, and at least one of a central processing unit (CPU), an application processor (AP), a graphics processing unit (GPU), a communication processor (CP), an image signal processor (ISP), and a controller.

Data information necessary for an operation of the processor 1200 or the display module 1100 may be stored in the memory 1300. When the processor 1200 executes an application stored in the memory 1300, an image data signal and/or an input control signal may be transmitted to the display module 1100, and the display module 1100 may process the received signal to output image information through a display screen.

The power module 1400 may include a power supply module, such as a power adapter or a battery device, and a power conversion module configured to convert power supplied by the power supply module to generate power necessary for an operation of the electronic apparatus 1000.

At least one of the components of the electronic apparatus 1000 described above may be included in the display apparatus 1 according to one or more of the embodiments described above. In one or more embodiments, among individual modules that are functionally included in a single module, some may be included in the display apparatus, and others may be provided separately from the display apparatus. For example, the display apparatus 1 may include the display module 1100, and the processor 1200, the memory 1300, and the power module 1400 may be provided as another apparatus within the electronic apparatus 1000, instead of within the display apparatus 1.

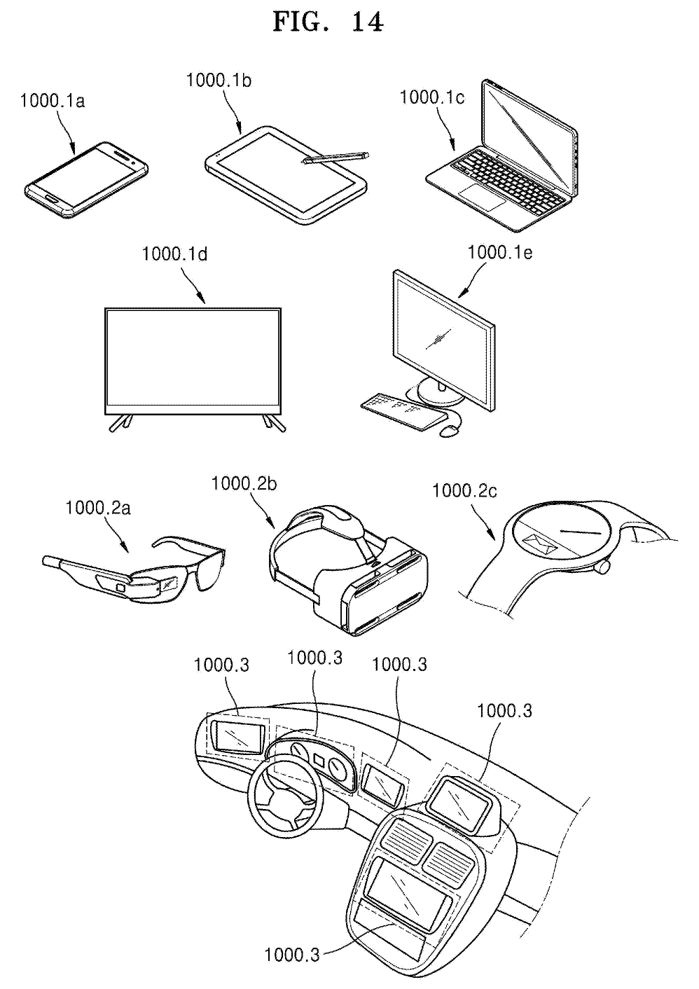

FIG. 14 is a set of schematic diagrams of electronic apparatuses according to various embodiments.

Referring to FIG. 14, various electronic apparatuses to which the display apparatus 1 according to embodiments is applied may include electronic apparatuses for displaying an image, such as a smart phone 1000.1a, a tablet PC 1000.1b, a laptop computer 1000.1c, a television (TV) 1000.1d, or a desktop monitor 1000.1e, wearable electronic apparatuses including a display module, such as smart glasses 1000.2a, an HMD 1000.2b, or a smart watch 1000.2c, and vehicular electronic apparatuses 1000.3 including a display module, such as a CID arranged on an instrument panel, center fascia, or dashboard of a vehicle, or a room mirror display.

According to one or more embodiments of the present disclosure, it may be possible to provide a display apparatus having improved reliability and display quality.

However, the effects of the present disclosure are not limited to the foregoing, and other unmentioned effects will be clearly understood by those of skill in the art from the following description.

Each of the embodiments described above may be implemented independently, but the structure of each embodiment may be applied to other embodiments in combination.

Although the present disclosure has been described with reference to the embodiments shown in the drawings, which are merely exemplary, it will be understood by those skilled in the art that various modifications and equivalent other embodiments are possible therefrom. Accordingly, the true technical protection scope of the present disclosure should be defined by the technical spirit of the appended claims.

The particular implementations shown and described herein are illustrative examples of the embodiments and are not intended to otherwise limit the scope of the embodiments in any way. In addition, no item or component is essential to the practice of the present disclosure unless the item or component is specifically described as being “essential” or “critical”.

The term “the” and other demonstratives similar thereto in the descriptions of embodiments (especially in the following claims) should be understood to include a singular form and plural forms. Further, recitation of ranges of values herein are merely intended to serve as a shorthand method of referring individually to each separate value falling within the range, unless otherwise indicated herein, and each separate value is incorporated into the specification as if it were individually recited herein. Finally, operations of all methods described herein may be performed in any suitable order unless otherwise indicated herein or otherwise clearly contradicted by context. The embodiments are not limited to the described order of the operations. The use of any and all examples, or exemplary language in embodiments, is intended merely to better illuminate the embodiments and does not pose a limitation on the scope of the embodiments unless otherwise claimed. Also, numerous modifications and adaptations will be readily apparent to those skilled in the art without departing from the spirit and scope of the present disclosure.

What is claimed is:

1. A display apparatus comprising two pixels adjacent to each other in a first direction,
wherein the two pixels respectively comprise a light-emitting device, and a transistor and a capacitor electrically connected to the light-emitting device,
wherein the capacitor comprises a bottom metal, a gate pattern, and a source/drain pattern stacked in the order stated, and
wherein a signal line extends in a second direction perpendicular to the first direction between the respective bottom metals of the two pixels, and the signal line is in a same layer as the respective bottom metals.

2. The display apparatus of claim 1, wherein, with regard to one or both of the two pixels, a shortest distance between the signal line and the bottom metal in the first direction is greater than a shortest distance between the signal line and the source/drain pattern in the first direction.

3. The display apparatus of claim 1, wherein, with regard to one or both of the two pixels, a shortest distance between the signal line and the gate pattern in the first direction is greater than a shortest distance between the signal line and the source/drain pattern in the first direction, and a shortest distance between the signal line and the bottom metal in the first direction.

4. The display apparatus of claim 1, wherein the signal line is a driving voltage line.

5. The display apparatus of claim 4, further comprising a sub-voltage line in a same layer as the source/drain pattern, and on the driving voltage line.

6. The display apparatus of claim 1, wherein the signal line is a data line.

7. The display apparatus of claim 6, wherein the data line comprises a first data line and a second data line apart from each other in the first direction.

8. The display apparatus of claim 1, wherein, with regard to one or both of the two pixels, in the capacitor, an entirety of the gate pattern is within an area of the source/drain pattern in a third direction perpendicular to the first direction and the second direction.

9. The display apparatus of claim 1, wherein, with regard to one or both of the two pixels, in the capacitor, an entirety of the gate pattern is within an area of the bottom metal in a third direction perpendicular to the first direction and the second direction.

10. The display apparatus of claim 1, wherein, with regard to one or both of the two pixels, in the capacitor, an entirety of the bottom metal is within an area of the source/drain pattern in a third direction perpendicular to the first direction and the second direction.

11. A display apparatus comprising:
two pixels adjacent to each other in a first direction, each pixel comprising a capacitor comprising a bottom metal, a gate pattern, and a source/drain pattern that are stacked in this order; and
a signal line between respective bottom metals of the two pixels,
wherein, with regard to one or both of the two pixels, a shortest distance between the signal line and the gate pattern in the first direction is greater than:
a shortest distance between the signal line and the source/drain pattern in the first direction, and
a shortest distance between the signal line and the bottom metal in the first direction.

12. An electronic apparatus comprising:
a processor configured to provide image data; and
a display apparatus configured to receive the image data and display an image based on the image data,
wherein the display apparatus comprises
two pixels adjacent to each other in a first direction, each pixel comprising a capacitor comprising a bottom metal, a gate pattern, and a source/drain pattern stacked in this order,
a signal line between respective bottom metals of the two pixels,
wherein, with regard to one or both of the two pixels, a shortest distance between the signal line and the bottom metal is greater than a shortest distance between the signal line and the source/drain pattern.

13. The electronic apparatus of claim 12, wherein, with regard to one or both of the two pixels, a shortest distance between the signal line and the gate pattern is greater than the shortest distance between the signal line and the source/drain pattern, and the shortest distance between the signal line and the bottom metal.

14. The electronic apparatus of claim 12, wherein the signal line is a driving voltage line.

15. The electronic apparatus of claim 14, further comprising a sub-voltage line in a same layer as the source/drain pattern, and on the driving voltage line.

16. The electronic apparatus of claim 12, wherein the signal line is a data line.

17. The electronic apparatus of claim 16, wherein the data line comprises a first data line and a second data line apart from each other.

18. The electronic apparatus of claim 12, wherein, with regard to one or both of the two pixels in plan view, in the capacitor, an entirety of the gate pattern is within an area of the source/drain pattern.

19. The electronic apparatus of claim 12, wherein, with regard to one or both of the two pixels in plan view, in the capacitor, an entirety of the gate pattern is within an area of the bottom metal.

20. The electronic apparatus of claim 12, wherein, with regard to one or both of the two pixels in plan view, in the capacitor, an entirety of the bottom metal is within an area of the source/drain pattern.
